(19) United States
(12) Patent Application Publication
(10) Pub. No.: US 2023/0393471 A1
(43) Pub. Date: Dec. 7, 2023

(54) HYBRID POLYMER/CRYSTAL PHOTOMECHANICAL MATERIALS

(71) Applicant: The Regents of the University of Colorado, a body corporate, Denver, CO (US)

(72) Inventors: Ryan C. Hayward, Boulder, CO (US); Wenwen Xu, Boulder, CO (US)

(21) Appl. No.: 18/318,926

(22) Filed: May 17, 2023

Related U.S. Application Data
(60) Provisional application No. 63/342,915, filed on May 17, 2022.

(51) Int. Cl. G03F 7/039

(52) U.S. Cl. CPC G03F 7/039

(57) ABSTRACT

A hybrid polymer/crystal photomechanical composite material is described. The hybrid polymer/crystal photomechanical composite material includes a substrate having a top surface and a plurality of pores extending from the top surface into the interior of the substrate, and diaryl ethene (DAE) crystals disposed in each of the plurality of pores. The substrate may be made from polyethylene terephthalate (PETE). Methods for actuating the described hybrid polymer/crystal photomechanical composite material and devices incorporating therein the described hybrid polymer/crystal photomechanical composite material are also described.

### CROSS REFERENCE TO RELATED APPLICATIONS

This application claims priority to U.S. Provisional Patent Application No. 63/342,915, filed May 17, 2022, entitled “HYBRID POLYMER/CRYSTAL PHOTOMECHANICAL MATERIALS”, the entirety of which is hereby incorporated by reference.

### STATEMENT REGARDING FEDERALLY SPONSORED RESEARCH

This invention was made with government support under grant number N00014-18-1-2624 awarded by the Office of Naval Research. The government has certain rights in the invention.”

### BACKGROUND

Photomechanical materials convert light to work, motion and/or changes in shape and/or properties of the photomechanical material. Light may therefore be advantageously used as a source of energy and information when used to control the mechanical response (i.e., actuation) of photomechanical materials. Light source characteristics such as wavelength, mode and polarization control can be used to obtain different photomechanical responses from photomechanical material. Furthermore, the use of light to actuate photomechanical materials allows for large amounts of power and information to be transmitted without heavy or easily corroded cables, and also does not require RF shielding. However, currently known photomechanical materials typically suffer from modest specific work and low thermodynamic efficiency.

Recent studies have looked at crystals as a platform to optimize work output when using light as a source of energy. For example, photochromophores can absorb photons and reorganize their molecular structures via photochemical processes. This has generally led to packing photochromophores into 3D ordered crystals that change shape upon exposure to light. This change in molecular scale geometry can be collectively amplified to the macroscopic scale. However, challenges with such bulk photomechanical crystals exist. Most problematic is that bulk crystals tend to fracture due to internal light-induced stress. While micro- or nanocrystals can deform and remain intact, their work output is not high enough for practical use.

Accordingly, a need exists for improved photomechanical materials capable of outputting relatively high amounts of work while still being stable and long-lasting.

### SUMMARY

This Summary is provided to introduce a selection of concepts in a simplified form that are further described below in the Detailed Description. This Summary, and the foregoing Background, is not intended to identify key aspects or essential aspects of the claimed subject matter. Moreover, this Summary is not intended for use as an aid in determining the scope of the claimed subject matter.

In some embodiments, a hybrid polymer/crystal photomechanical composite material is disclosed, the hybrid polymer/crystal photomechanical composite material including a substrate having a top surface and a plurality of pores extending from the top surface into the interior of the substrate, and diaryl ethene (DAE) crystals disposed in each of the plurality of pores. The substrate may be made from polyethylene terephthalate (PETE).

In some embodiments, a method of actuating a hybrid polymer/crystal photomechanical composite material is disclosed, the method including providing a hybrid polymer/crystal photomechanical composite material as described in the preceding paragraph, and propagating light at the surface of the hybrid polymer/crystal photomechanical composite material. Propagating light at either surface causes the hybrid polymer/crystal photomechanical composite material to bend towards the top surface.

In some embodiments, a device is disclosed, the device having incorporated therein a hybrid polymer/crystal photomechanical composite material as described in the preceding paragraphs. The hybrid polymer/crystal photomechanical composite material is configured to be actuated by propagating light at the hybrid polymer/crystal photomechanical composite material to thereby perform work on the device.

These and other aspects of the technology described herein will be apparent after consideration of the Detailed Description and Figures herein. It is to be understood, however, that the scope of the claimed subject matter shall be determined by the claims as issued and not by whether given subject matter addresses any or all issues noted in the Background or includes any features or aspects recited in the Summary.

### BRIEF DESCRIPTION OF THE DRAWINGS

Non-limiting and non-exhaustive embodiments of the disclosed technology, including the preferred embodiment, are described with reference to the following figures, wherein like reference numerals refer to like parts throughout the various views unless otherwise specified.

FIGS. 1A and 1B are illustrations of the chemical structures for PETE and DAE, respectively.

FIG. 2 are illustrations of various substrates suitable for use in hybrid polymer/crystal photomechanical composite materials described herein.

FIG. 3 is an illustration of a method for forming the hybrid polymer/crystal photomechanical composite materials described herein.

FIG. 4 is an illustration of a method for actuating the hybrid polymer/crystal photomechanical composite materials described herein.

### DETAILED DESCRIPTION

Embodiments are described more fully below with reference to the accompanying Figures, which form a part hereof and show, by way of illustration, specific exemplary embodiments. These embodiments are disclosed in sufficient detail to enable those skilled in the art to practice the invention. However, embodiments may be implemented in many different forms and should not be construed as being limited to the embodiments set forth herein. The following detailed description is, therefore, not to be taken in a limiting sense.

Described herein are various embodiments of a hybrid polymer/crystal photomechanical composite material. The material is configured to change shape when light is propagated at the material, primarily due to the photochemical nature of the crystal component of the material. That is to say, the molecular structure of the crystal material changes shape when light is propagated thereat, and the change in shape of the crystal material cause the composite material to change shape. This change in shape can cause the composite material to perform work. As described herein and in Appendices A and B included herewith, it has been discovered that the composite material described herein exhibits improved performance as compared to previously known photomechanical materials, such as improved work density, photon-to-work efficiency, and response time.

The composite material described herein generally includes a polymer substrate having a top surface and a plurality of pores extending from the top surface into the interior of the substrate, and a photochemical crystal material disposed in each of the plurality of the pores. When light is propagated at either surface of the composite material, the molecular structure of the photochemical crystal material within the pores of the substrate changes shape. This change in molecular shape applies a strain to the substrate, which in turn cause the shape of the substrate to change. In some embodiments, substrate changes shape by bending towards the top surface.

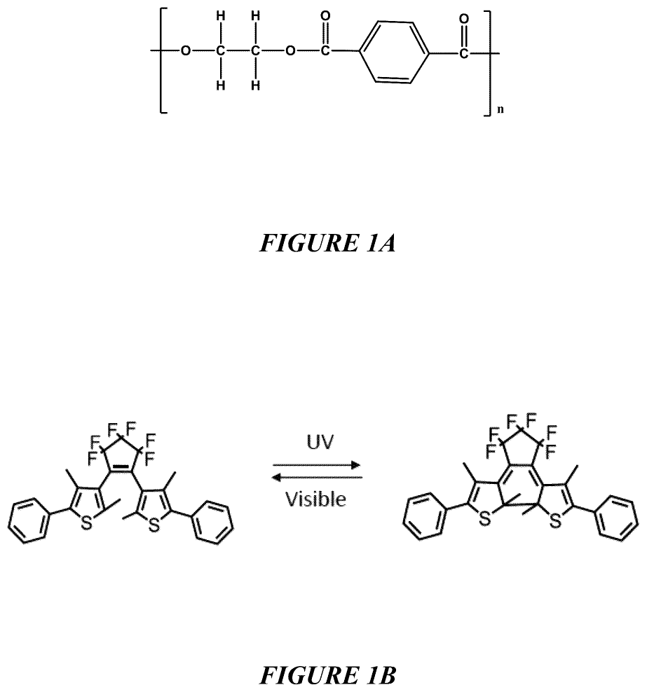

The substrate is generally comprised of polyethylene terephthalate (PETE). FIG. 1A provides an illustration of the chemical structure of PETE. The dimensions and overall shape of the substrate is generally not limited, though in some embodiments, the substrate has a general sheet or disk shape with a relatively small thickness as compared to the width and length dimensions of the substrate. In some embodiments, the thickness of the substrate is in the micrometer range, such as from about 11 to about 22 micrometers.

PETE includes rigid aromatic rings and ester groups on its backbone and has good resistance to heat and most organic solvents, thus making it compatible with crystal growth conditions. The Young's modulus for PETE is around 2 GPa, and as described in more detail herein and in Appendices A and B included herewith, performs well as a photomechanical composite material when used in conjunction with a crystal material having a similar Young's modulus, such as is the case for DAE microcrystals. PETE is a typical semicrystalline material in the triclinic system (a=4.56 Å; b=5.94 Å; c=10.75 Å; α=98.5°; β=118.0°; γ=112.0°). When the PETE-based substrate is made from an extrusion process, anisotropic distribution of PETE crystallites within the substrate is expected. X-ray scattering experiments as discussed in greater detail in Appendices A and B included herewith reveal the orientation of PETE in the substrate.

As described previously, the substrate comprising PETE includes a plurality of pores extending from a top surface into the interior of the substrate. These pores are generally randomly distributed throughout the substrate. In some embodiments, the pores have a micron or submicron length and may or may not extend all the way through the thickness of the substrate. The pores may be created in the substrate via a track-etching process. The size and dimensions of the pores are ultimately selected to confine the crystal size of the DAE disposed therein to within the submicron range.

Each pore in the PETE-based substrate has a longitudinal axis. In some embodiments, the orientation of the longitudinal axis is aligned such that it forms a 90-degree angle with the plane of the top surface of the substrate. In other embodiments, the longitudinal axis may form an angle with the plane of the top surface, the angle being within the range of from about 40 to about 90 degrees. Altering the orientation of the longitudinal axis of the pores offers an opportunity to tune the crystal growth direction within the substrate as discussed in more detail in Appendices A and B included herewith.

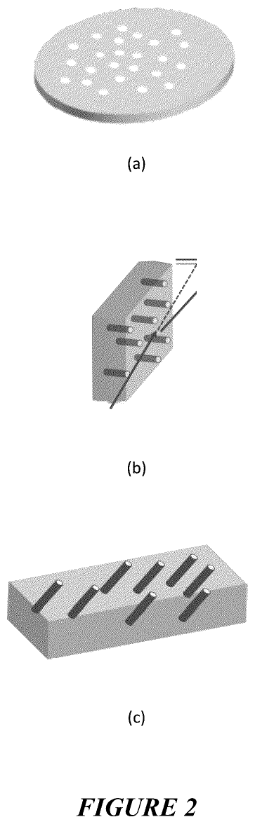

FIG. 2 illustrates various embodiments of the substrate as described in the preceding paragraphs. At (a), an illustration of a disk-shaped substrate having a plurality of DAE crystal-filled pores is shown. At (b), an embodiment of the substrate wherein the longitudinal axis of the pores is aligned perpendicularly to the top surface of the substrate is shown, while at (c), an embodiment of the substrate wherein the longitudinal axis of the pores is aligned at an angle to the top surface of the substrate (such as at a 60-degree angle to the top surface) is shown.

Disposed within the plurality of pores formed in the substrates is DAE crystals. Any suitable species of DAE can be used in the embodiments described herein. In one non-limiting example, the DAE is 1,2-bis(2,4-dimethyl-5-phenyl-3-thienyl)perfluorocyclopentene. As shown in FIG. 1B, 1,2-bis(2,4-dimethyl-5-phenyl-3-thienyl)perfluorocyclopentene toggles between a ring-closed and ring-open isomer when exposed to different types of light. More specifically, the DAE species toggles from ring-open to ring-closed when exposed to UV light, and toggles from ring-closed to ring-open when exposed to visible light. The DAE molecular may toggle back and forth between its two forms more than 30,000 times without significant degradation in its crystalline form.

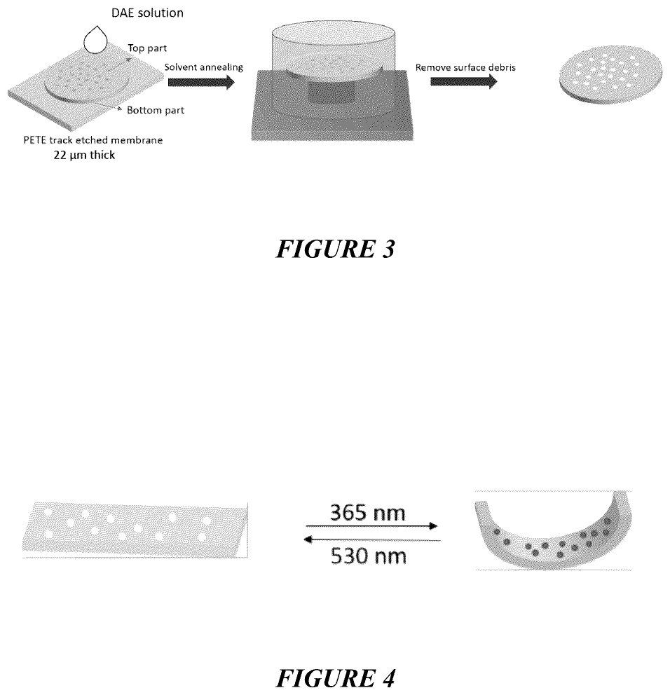

With reference to FIG. 3, an exemplary, though non-limiting, method for making the composite material described herein generally includes providing the PETE-based substrate having pores formed therein, depositing DAE solution over the substrate and into the pores, and annealing the assembly to promote crystallization of the DAE within the pores. In one specific example, 100 μl of DAE solution (10% wt. in DMF) was deposited to a track etched PETE disk (disk diameter: 1.3 cm, pore diameter: 0.8 μm and thickness: 22 μm) on top of a solvent-resistant film which was placed inside a loosely capped glass jar. The whole assembly was annealed at 53 degrees in a DMF vapor environment overnight. A cotton tip applicator was used to remove the bulk crystals covering the membrane.

The DAE crystals disposed within the pores of the PETE-based substrate are epitaxially aligned. In-plane anisotropic semicrystalline polymer substrates have been reported to epitaxially guide the organic crystal overlayers' growth which can be attributed to the lattice match between the overlayer and substrate. Thus, the biaxially alignment of DAE crystals inside the PETE templates to create single-crystal-like composite is expected. Further discussion of the alignment of DAE crystals within the pores and with respect to the PETE substrate is provided in Appendices A and B included herewith.

With respect now to FIG. 4, the actuation of the composite material is illustrated. The substrate has a top surface (i.e., the surface from which the pores extend into the interior of the substrate) and a bottom surface opposite the top surface. The bottom surface may be in contact with a solvent resistant urea resin-based substrate, film or sheet. After solvent annealing as described previously, the composite material bends slightly towards the top surface. When UV light is propagated at the either surface of the composite material, the composite material bends further towards the top side. In some embodiments, the UV light is propagated perpendicular to the either surface, in which case the composite material always bends toward the top surface, irrespective of the light exposure direction. When UV exposure to bottom side of the composite material is sufficiently long to reach photostationary state (PSS), flipping the composite material and irradiating from the top surface will not change its bending curvature. This suggests that UV light can penetrate through the thickness of the composite material without skin layer formation commonly known for condensed dye system.

In an actuation event, the strain energy generated by the microcrystals will dissipate through the surrounding substrate and deform the whole composite material. While an overly stiff substrate will hinder the crystal displacement and an overly soft substrate will not generate high enough force, the final work output of a substrate having elastic impedance match with the embedded crystals can be maximized, assuming an optimal loading.

The performance of the composite material depends at least in part on the match between the DAE molecular orientation and the substrate plane. In some embodiments, the pores of the PTFE-based substrate are designed to be at a 60-degree angle with the top surface of the substrate to thereby change the orientations of the DAE crystals embedded within the pores. With this new geometry the photostrain is increased from 1% (at vertical pore orientation) to 2.5% (at 60 degrees angled pore) for a thickness of 22 micrometers. Similar performance (2.5% strain) was also achieved for 11 micrometer thick materials with non-tilted pores.

The photostrain of the composite material does not depend on the light intensity, but instead on the UV dosage applied. The angled pore configuration generates more strain than a vertical pore orientation under the same UV dosage. Furthermore, the response speed of the composite material is highly related to the light intensity. For example, under 2.2 W/cm² 365 nm light, the response time of the composite material can be as short as 10 ms.

The composite material described herein may be incorporated into any number of devices such that the composite material, when actuated upon the propagation of light thereat, can perform work to the benefit of the operation of the device. For example, the change in shape of the composite material that occurs upon application of light can be used to carry out or facilitate any variety of functions within a device. Non-limiting examples of device in which the composite material may be incorporated include wearable technology and soft robot technology.

From the foregoing, it will be appreciated that specific embodiments of the invention have been described herein for purposes of illustration, but that various modifications may be made without deviating from the scope of the invention. Accordingly, the invention is not limited except as by the appended claims.

Although the technology has been described in language that is specific to certain structures and materials, it is to be understood that the invention defined in the appended claims is not necessarily limited to the specific structures and materials described. Rather, the specific aspects are described as forms of implementing the claimed invention. Because many embodiments of the invention can be practiced without departing from the spirit and scope of the invention, the invention resides in the claims hereinafter appended.

Unless otherwise indicated, all number or expressions, such as those expressing dimensions, physical characteristics, etc., used in the specification (other than the claims) are understood as modified in all instances by the term “approximately”. At the very least, and not as an attempt to limit the application of the doctrine of equivalents to the claims, each numerical parameter recited in the specification or claims which is modified by the term “approximately” should at least be construed in light of the number of recited significant digits and by applying rounding techniques. Moreover, all ranges disclosed herein are to be understood to encompass and provide support for claims that recite any and all sub-ranges or any and all individual values subsumed therein. For example, a stated range of 1 to 10 should be considered to include and provide support for claims that recite any and all sub-ranges or individual values that are between and/or inclusive of the minimum value of 1 and the maximum value of 10; that is, all sub-ranges beginning with a minimum value of 1 or more and ending with a maximum value of 10 or less (e.g., 5.5 to 10, 2.34 to 3.56, and so forth) or any values from 1 to 10 (e.g., 3, 5.8, 9.9994, and so forth).

I/We claim:

1. A hybrid polymer/crystal photomechanical composite material, comprising:
a substrate having a top surface and a plurality of pores extending from the top surface into the interior of the substrate, wherein the substrate comprises polyethylene terephthalate (PETE); and
wherein at least a portion of each of the plurality of pores is filled with diaryl ethene (DAE) crystals.

2. The hybrid polymer/crystal photomechanical composite material of claim 1, wherein the DAE crystals within each of the pores are epitaxially aligned.

3. The hybrid polymer/crystal photomechanical composite material of claim 1, wherein the entirety of each of the plurality of pores is filled with diaryl ethene crystals.

4. The hybrid polymer/crystal photomechanical composite material of claim 1, wherein the orientation of the longitudinal axis of each of the plurality of pores is about perpendicular to the top surface of the substrate.

5. The hybrid polymer/crystal photomechanical composite material of claim 1, wherein the orientation of the longitudinal axis of each of the plurality of pores is at about a 60 degree angle to the top surface of the substrate.

6. The hybrid polymer/crystal photomechanical composite material of claim 1, wherein the orientation of the longitudinal axis of each of the plurality of pores is at an angle with the top surface in the range of from about 40 to about 90 degrees.

7. The hybrid polymer/crystal photomechanical composite material of claim 1, wherein the substrate is anisotropic.

8. The hybrid polymer/crystal photomechanical composite material of claim 1, wherein the diaryl ethene is 1,2-bis(2,4-dimethyl-5-phenyl-3-thienyl)perfluorocyclopentene.

9. The hybrid polymer/crystal photomechanical composite material of claim 1, wherein each of the plurality of pores has a length in the sub-micrometer range.

10. The hybrid polymer/crystal photomechanical composite material of claim 1, wherein the DAE crystals are biaxially aligned within the pores.

11. A method of actuating a hybrid polymer/crystal photomechanical composite material, comprising:
providing a hybrid polymer/crystal photomechanical composite material as claimed in claim 1; and
propagating light at the either surface of the hybrid polymer/crystal photomechanical composite material;
wherein propagating the light at either surface causes the hybrid polymer/crystal photomechanical composite material to bend towards the top surface.

12. The method of claim 11, wherein the light is UV light.

13. The method of claim 11, wherein the propagating the light at the either surface comprises propagating the light at a direction perpendicular to the either surface.

14. A device incorporating therein a hybrid polymer/crystal photomechanical composite material as recited in claim 1, wherein the hybrid polymer/crystal photomechanical composite material is configured to be actuated by propagating light at the hybrid polymer/crystal photomechanical composite material to thereby perform work on the device.
